(19) United States
(12) Patent Application Publication
(10) Pub. No.: US 2012/0140953 A1
(43) Pub. Date: Jun. 7, 2012

(54) MULTI-AMPLIFIER AUDIO MODULE FOR A MULTICHANNEL SPEAKER, AND MULTI-AMPLIFIER AUDIO MODULE HOUSING ASSEMBLY FOR SAME

(76) Inventor: Seo Kyung Kim, Seoul (KR)

(21) Appl. No.: 13/390,112

(22) PCT Filed: Aug. 18, 2010
(86) PCT No.: PCT/KR10/05441

§ 371 Date: Feb. 12, 2012

(30) Foreign Application Priority Data
Aug. 20, 2009 (KR) 10-2009-0077113

(51) Int. Cl. H03G 5/00

(52) U.S. Cl. 381/103

(57) ABSTRACT

The present invention relates to a multi-amplifier audio module for a multichannel speaker. The multi-amplifier audio module comprises a plurality of amplifier units connected to a power source and connected to each other to amplify an input audio signal. A plurality of speakers for outputting the amplified audio signal, an equalizer for adjusting the amplified audio signal for each frequency band, and a volume controller for controlling the volume of the amplified audio signal, are connected to each of the amplifier units.

### TECHNICAL FIELD

The present invention relates to a multi-amplifier audio module for a multichannel speaker and a prefabrication type multi-amplifier audio module housing for the same, and in particular to a multi-amplifier audio module for a multichannel speaker and a prefabrication type multi-amplifier audio module housing assembly for the same which make it possible to overcome a power down problem of a multichannel speaker installed at a single amplifier with a surround sound effect.

### BACKGROUND ART

An audio module generally comprises a single amplifier for amplifying an audio input, an equalizer controlling the frequency of an audio output, and a volume controller controlling the volume of an audio output. The audio signal inputted by way of an audio input is amplified by means of an amplifier, and is outputted in audio forms by way of a multichannel speaker connected to an amplifier.

FIG. 1 is a schematic view illustrating a construction of a conventional audio input/output module.

As shown in FIG. 1, the conventional audio module comprises a single amplifier AMP; 1 amplifying an audio signal inputted from an audio input of an audio module, an equalizer EQ; 1a outputting a certain audio output by way of a low tone of a frequency below about 500 Hz, a middle tone output of a frequency of 500 Hz-1 Khz and a high tone output of a frequency of above 1 kHz from an audio output signal from the amplifier 1, and a volume controller VOL; 1b controlling the level of an audio output controlled by means of the equalizer, namely, the volume of the audio.

The amplifier 1 is connected with left and right speakers L and R which output a frequency output of a stereo sound, and is further connected with left and right speakers L and R at each speaker so as to cover a sound range frequency such as a high tone, a middle tone and a low tone.

The conventional amplifier which is generally used for an audio module of the above connection structure is a low or middle price amplifier which has a low output of above 1 kw. In this case, the output of each main speaker connected to the above amplifier is actually divided into as many parts as the number of the speakers connected, so each left and right main speaker has an output of 500 w, and two speakers connected with the left and right main speakers have an output divided to an output of 250 w.

The audio signal inputted into the audio module is amplified up to an output level of 1 kw by way of the amplifier 1; however the audio signal outputted by way of the speaker has an output of 250 w, so it is impossible to obtain a surround sound.

In order to overcome the above problems, a high power amplifier might be used; however it is very expensive, so the application of the same is not economical and cost-effectively bad.

When a plurality of speakers are installed under an environment corresponding to the inside of a building where it is not good for audio-listening, even when the same audio signals are inputted, each speaker outputs tones of different frequencies depending on their installation positions such as wall, a floor, etc. Since the conventional audio module is characterized in that the tone controls by means of an equalizer are identically applied to all speakers, it is is impossible to control the tones of speakers depending on the installation positions of the speakers, so the best quality of sound is hard to achieve.

### DISCLOSURE OF INVENTION

Accordingly, the present invention overcomes the above problems, and it is an object of the present invention to provide a multi-amplifier audio module for a multichannel speaker which makes it possible to generate a high power audio from a multichannel speaker even when a low power amplifier is used, and the volumes and tones of each speaker can be individually controlled.

It is another object of the present invention to provide a prefabrication type multi-amplifier audio module housing assembly for a multichannel speaker which has a high power audio and provides an installation expandability of a multichannel speaker.

To achieve the above objects, there is provided a multi-amplifier audio module for a multichannel speaker which comprises a plurality of amplifier units connected with an electric power and interconnected to amplify an audio input signal, each amplifier unit comprising a plurality of speakers outputting the amplified audio signal, an equalizer controlling the amplified audio signal by the frequency, and a volume controller controlling the volume of the amplified audio signal.

In an embodiment of the present invention, the amplifier unit comprises a first middle, low output amplifier, with the speakers, the equalizer and the volume controller being connected with the first middle, low output amplifier, respectively.

In an embodiment of the present invention, the amplifier unit comprises a first middle, low output amplifier and a second middle, low output amplifier, and the equalizer and the volume controller are connected between the first middle, low output amplifier, and the second middle, low output amplifier, and the speakers are connected with the second middle, low output amplifier.

To achieve the above objects according to another embodiment of the present invention, there is provided a multi-amplifier audio module housing assembly for a multichannel speaker, comprising a plurality of housing bodies which are interconnected and each include a single amplifier unit connected with a plurality of speakers which are connected with an electric power and amplify an audio input signal and output the amplified audio signal; an equalizer which controls the amplified audio signal by the frequency; and a volume controller controlling the volume of the amplified audio signal, and each of the housing bodies comprising male and female type engaging members for engagement; male and female electric power connection terminals for electric connections; and make and female audio terminals for a connection of audio is signals.

In an embodiment of the present invention, the amplifier unit of the housing assembly has the same construction as the construction of the previous embodiment.

In an embodiment of the present invention, the engaging part is formed of a protrusion and a groove which are engaged with each other.

### Advantageous Effects

According to the construction of a multi-amplifier audio module for a multichannel speaker according to the present invention, a high power audio can be generated even when a low power amplifier is used, and the volume and tone of each speaker can be individually controlled.

According to the construction of a prefabrication type multi-amplifier audio module housing assembly for a multichannel speaker, a high power audio can be generated, and an installation expandability of a multichannel speaker is to possible.

### BRIEF DESCRIPTION OF THE DRAWINGS

The present invention will become better understood with reference to the accompanying drawings which are given only by way of illustration and thus is are not limitative of the present invention, wherein;

FIG. 1 is a schematic view illustrating a construction of a conventional audio amplifier module;

FIG. 2 is a schematic view illustrating a construction of a multi-amplifier audio module for a multichannel speaker according to an embodiment of the present invention;

FIG. 3 is a schematic view illustrating a construction of a multi-amplifier audio module for a multichannel speaker according to another embodiment of the present invention; and

FIG. 4 is a disassembled and assembled perspective view illustrating a multi-amplifier audio module housing assembly for a multichannel speaker according to another aspect of the present invention.

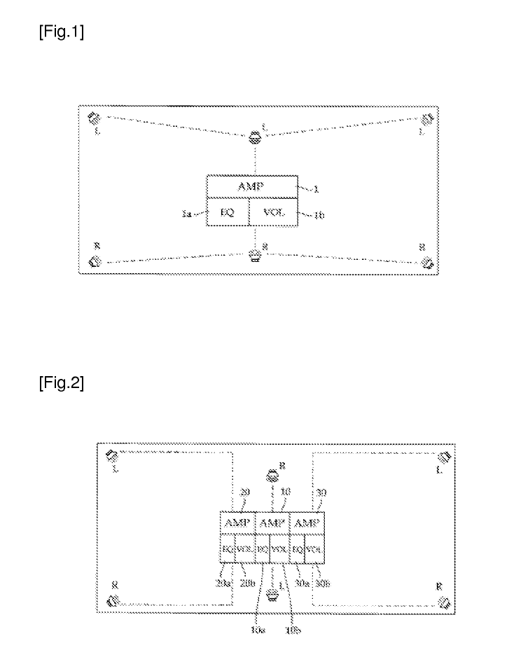

### BEST MODES FOR CARRYING OUT THE INVENTION

The preferred embodiments of the present invention will be described in details with reference to the accompanying drawings.

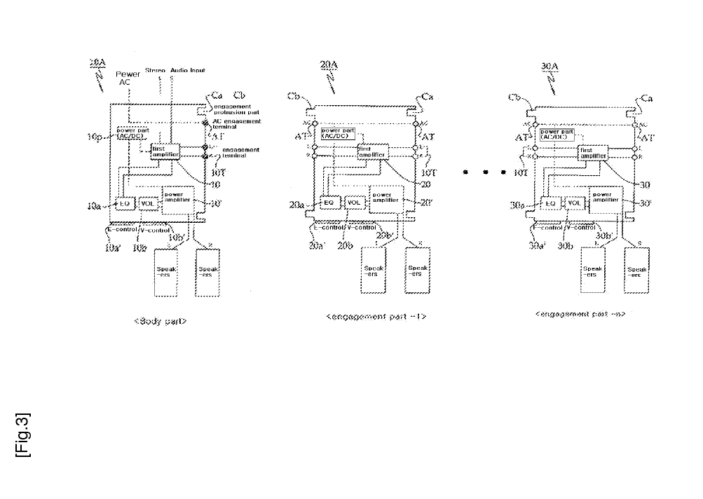

FIG. 2 is a schematic view illustrating a construction of a multi-amplifier audio module for a multichannel speaker according to an embodiment of the present invention, and FIG. 3 is a schematic view illustrating a construction of a multi-amplifier audio module for a multichannel speaker according to another embodiment of the present invention.

As shown in FIG. 2, the multi-amplifier audio module for a multichannel speaker according to the embodiment of FIG. 2 is formed of a plurality of amplifier units (three units are shown in the drawing) 10, 20 and 30 for amplifying the audio inputs.

Each amplifier unit includes a power part 10p, 20p and 30p (refer to FIG. 3) connected with external AC power, with the power parts being connected by way of a certain connector.

To amplifier units 10, 20 and 30 are connected a plurality of left and right speakers L and R outputting amplified audio signals, equalizers EQ; 10a, 20a and 30a controlling the amplified audio signals by the frequency by way of control dials 10a′, 20a′ and 30a′, and volume controllers 10b, 20b and 30b controlling the volumes of the amplified audio signals by way of the control dials 10b′, 20b′ and 30b′.

The amplifier unit might be formed of one or more middle and low output amplifiers and in the embodiment of FIG. 2, it is formed of a single amplifier 10, 20, 30, and in the embodiment of FIG. 3, it is formed of two amplifiers 10, 10′, 20, 20′ and 30, 30′, the difference of which lies in the number of the amplifiers, and the construction of which are same.

In other words, the amplifier unit of the embodiment of FIG. 2 is formed of a single first middle and low power amplifier 10, 20 or 30, and the speakers L and R, the equalizers 10a, 20a and 30a, and the volume controllers 10b, 20b and 30b are connected with the first amplifier 10, and the amplifier unit of the embodiment of FIG. 3 is formed of a first middle and low power amplifier 10, 20 or 30 and a second middle and low power amplifier 10′, 20′ or 30′, and the equalizers 10a, 20a an 30a and the volume controllers 10b, 20b and 30b are connected between the first amplifier 10, 20 or 30 and the second amplifier 10′, 20′ or 30′. The speakers L and R are connected with the second amplifier 10′, 20′ or 30′.

The amplifier unit formed of a single amplifier unit, namely, a single amplifier 10, 20 or 30 of the embodiment of FIG. 2 is directed to obtaining a certain audio output by amplifying an initial audio input signal. For example, when the output of the audio input is 0.9 kw, the audio input is divided into three audio modules, so each input becomes 0.3 kw. In this case, it is impossible to obtain a desired level of output if only the above input is outputted by way of the speakers, so each amplifier unit amplifies the sound 10 times, and the speaker of each amplifier module can output an audio output of 3 kw, whereby a desired audio output can be obtained.

The amplifier unit of the embodiment of FIG. 3 is formed of two amplifiers and is directed to generating a certain audio output in such a way to amplify an initial audio signal by way of a first amplifier 10, 20 or 30, and the amplified audio signal is amplified by means of a second amplifier 10′, 20′ or 30′, thus generating a desire level of audio output.

The present invention is directed to a prefabrication type multi-amplifier audio module housing assembly for a multichannel speaker which makes it possible to obtain a high power audio and an installation expandability of multichannel speakers.

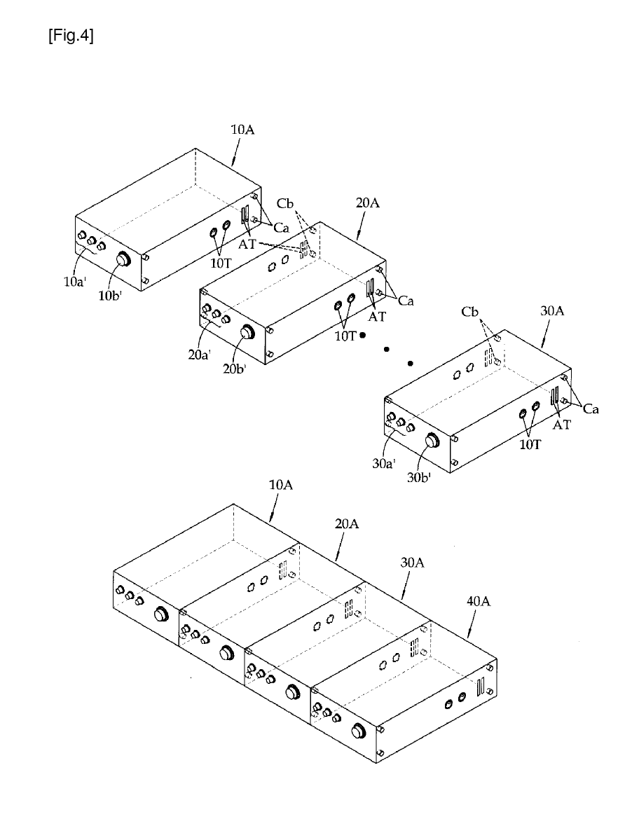

FIG. 4 is a disassembled and assembled perspective view illustrating a multi-amplifier audio module housing assembly for a multichannel speaker according to another aspect of the present invention, in which the construction of the audio module of FIG. 3 is applied to the housing.

As shown in FIGS. 3 and 4, the multi-amplifier audio module housing assembly comprises a plurality of speakers connected with an electric power thus amplifying an audio signal and outputting the amplified audio signal, equalizers 10a, 20a and 30a adjusting the amplified audio signal by the frequencies by way of control dials 10a 20a and 30a, and a plurality of housing bodies 10A, 20A and 30A interconnected while accommodating single amplifier unit connected with the volume controller 10b, 20b and 30b controlling the volumes of the amplified audio signals by way of the control dials 10b′, 20b′ and 30b′.

The audio module housings 10A, 20A, 30A and 40A can be freely interconnected by the number the user wants. For the above assembly construction, the housing body comprises male and female type engaging parts Ca and Cb for an interconnection, male and female type power connection terminals AT for a power connected between them, and male and female type audio terminals 10T for a connection of an audio signal.

The amplifier unit of the housing assembly has the same construction as the construction of the previously embodiment of the present invention.

The engaging parts Ca and Cb are formed of a protrusion Ca and a groove Cb which are engaged with each other or alternatively they might be formed of other known mechanical connectors,

The power connection terminal AT and the audio terminal 10T serve to connect each audio module with an external electric power and transfer an input audio signal to the amplifies 10, 20 and 30 of a nearby audio module, for example, they might be male and female type connectors in the form of a socket or a jack structure.

The construction of the audio module housing assembly provides a high power audio and an installation expandability of a multichannel speaker.

1. A multi-amplifier audio module for a multichannel speaker, comprising:
a plurality of amplifier units which are connected with an electric power and are connected one another to amplify an audio input signal in a form of a multi-amplifier audio module for a multichannel speaker, said amplifier units each including:
a plurality of speakers outputting the amplified audio signal;
an equalizer adjusting the amplified audio signal by the frequency; and
a volume controller controlling the volume of the amplified audio signal.

2. The module of claim 1, wherein said amplifier unit comprises a first middle, low output amplifier, with the speakers, the equalizer and the volume controller being connected with the first middle, low output amplifier, respectively.

3. The module of claim 1, wherein said amplifier unit comprises a first middle, low output amplifier and a second middle, low output amplifier, and said equalizer and said volume controller are connected between the first middle, low output amplifier, and the second middle, low output amplifier, and said speakers are connected with the second middle, low output amplifier.

4. A multi-amplifier audio module housing assembly for a multichannel speaker, comprising:
a plurality of housing bodies which are interconnected and each include a single amplifier unit connected with a plurality of speakers which are connected with an electric power and amplify an audio input signal and output the amplified audio signal; an equalizer which controls the amplified audio signal by the frequency; and a volume controller controlling the volume of the amplified audio signal, and
each of said housing bodies comprising:
male and female type engaging members for engagement;
male and female electric power connection terminals for electric connections; and
male and female audio terminals for a connection of audio signals.

5. The assembly of claim 4, wherein said amplifier unit comprises a first middle, low output amplifier, and said equalizer and said volume controller are connected with the first middle, low output amplifier.

6. The assembly of claim 4, wherein said amplifier unit comprises a first middle, low output amplifier and a second middle, low output amplifier, and said equalizer and said volume controller are connected between the first middle, low output amplifier and the second middle, low output amplifier, and said speaker is connected with the second middle, low output amplifier.

7. The assembly of claim 4, wherein said engaging part is formed of a protrusion and a groove which are engaged with each other.
